(19) United States
(12) Patent Application Publication
(10) Pub. No.: US 2023/0403828 A1
(43) Pub. Date: Dec. 14, 2023

(54) WATER COOLING ASSEMBLY AND ELECTRONIC ASSEMBLY

(71) Applicant: COOLER MASTER CO., LTD., Taipei City (TW)

(72) Inventors: Chien-Liang LIN, Taipei City (TW); Shui-Fa TSAI, Taipei City (TW)

(73) Assignee: COOLER MASTER CO., LTD., Taipei City (TW)

(21) Appl. No.: 18/207,630

(22) Filed: Jun. 8, 2023

Related U.S. Application Data
(60) Provisional application No. 63/350,792, filed on Jun. 9, 2022.

(51) Int. Cl. H05K 7/20; G06F 1/20; G06F 1/18

(52) U.S. Cl. CPC H05K 7/20772; H05K 7/20263; H05K 7/20272; G06F 1/20; G06F 1/185; G06F 2213/0026

(57) ABSTRACT

A water cooling assembly is configured to be mounted at an electrical connector of a circuit board. The water cooling assembly includes a mounting plate and a water cooling radiator. The mounting plate includes a mounting portion and a plugging portion. The plugging portion is connected to a side of the mounting portion, and the plugging portion is configured to be inserted into the electrical connector of the circuit board. The water cooling radiator is fastened to the mounting portion of the mounting plate.

### CROSS-REFERENCE TO RELATED APPLICATIONS

This non-provisional application claims priority under 35 U.S.C. § 119(a) on Patent Application No(s). 63/350,792 filed in US, on Jun. 9, 2022, the entire contents of which are hereby incorporated by reference.

### TECHNICAL FIELD

The present disclosure relates to an electronic assembly, more particularly to an electronic assembly having a water cooling assembly.

### BACKGROUND

When an electronic device is operating, a great amount of heat can be generated. If the heat cannot be effectively dissipated, some problems, such as functional failure or shutdown, due to overheating may be caused to the electronic components in the electronic device. Therefore, a heat dissipation system is usually provided in the electronic device to ensure that the operation of the electronic device may not exceed the preset operating temperature range. Especially for a high performance electronic device, a water cooling heat dissipation system, such as a water cooling radiator is usually adopted for a better heat dissipation effect.

Generally, the water cooling radiator is additionally provided in a casing of a server. However, since the conventional server includes a plurality of electronic components, the inner space of the casing is limited, such that the water cooling radiator is difficult to be disposed in the server, thereby causing inconvenience in assembly. Therefore, how to save the inner space of the server while improving the convenience for installing the water cooling assembly in the server is an important issue to be solved

### SUMMARY

The present disclosure provides a water cooling assembly and an electronic assembly so as to save the inner space of the server while improving the convenience for installing the water cooling assembly in the server.

One embodiment of the disclosure provides a water cooling assembly configured to be mounted at an electrical connector of a circuit board. The water cooling assembly includes a mounting plate and a water cooling radiator. The mounting plate includes a mounting portion and a plugging portion. The plugging portion is connected to a side of the mounting portion, and the plugging portion is configured to be inserted into the electrical connector of the circuit board. The water cooling radiator is fastened to the mounting portion of the mounting plate.

Another embodiment of the disclosure provides an electronic assembly including a circuit board, an interface card, a water cooling heatsink and a water cooling assembly. The circuit board has a plurality of electrical connectors. The interface card is inserted into and electrically connected to one of the plurality of electrical connectors of the circuit board. The water cooling heatsink is mounted on the interface card. The water cooling assembly includes a mounting plate and a water cooling radiator. The mounting plate includes a mounting portion and a plugging portion. The plugging portion is connected to a side of the mounting portion, and the plugging portion is be inserted into another electrical connector of the circuit board. The water cooling radiator is fastened to the mounting portion of the mounting plate and is in fluid communication with the water cooling heatsink via pipes.

According to the water cooling assembly and the electronic assembly as described in the above embodiments, since the mounting plate for fastening the water cooling radiator is additionally provided in the water cooling assembly, when the inner space of the server is almost fully occupied by electronic components, the mounting plate can be inserted into one of the original electrical connectors of the circuit board to install the water cooling assembly. Accordingly, the distance between the water cooling assembly and the interface card can be shortened to save space via the small-sized mounting plate. In addition, the water cooling assembly can be assembled via the mounting plate inserted into one of the original electrical connectors merely, without additionally installing a plurality of fastening components configured to fasten the water cooling assembly. Therefore, the inner space of the server can be saved and the convenience for installing the water cooling assembly in the server can be improved.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective view of an electronic assembly in accordance with an embodiment of the disclosure;

FIG. 2 is a perspective view of a water cooling assembly of the electronic assembly in FIG. 1;

FIG. 3 is an exploded view of the water cooling assembly of the electronic assembly in FIG. 1;

FIG. 4 is a cross-sectional view of the water cooling assembly of the electronic assembly in FIG. 1;

FIG. 5 is a cross-sectional view of a first heat dissipation channel structure of the electronic assembly in FIG. 1;

FIG. 6 is a cross-sectional view of a fourth heat dissipation channel structure of the electronic assembly in FIG. 1;

FIG. 7 is a cross-sectional view of a second heat dissipation channel structure of the electronic assembly in FIG. 1; and

FIG. 8 is a cross-sectional view of a third heat dissipation channel structure of the electronic assembly in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

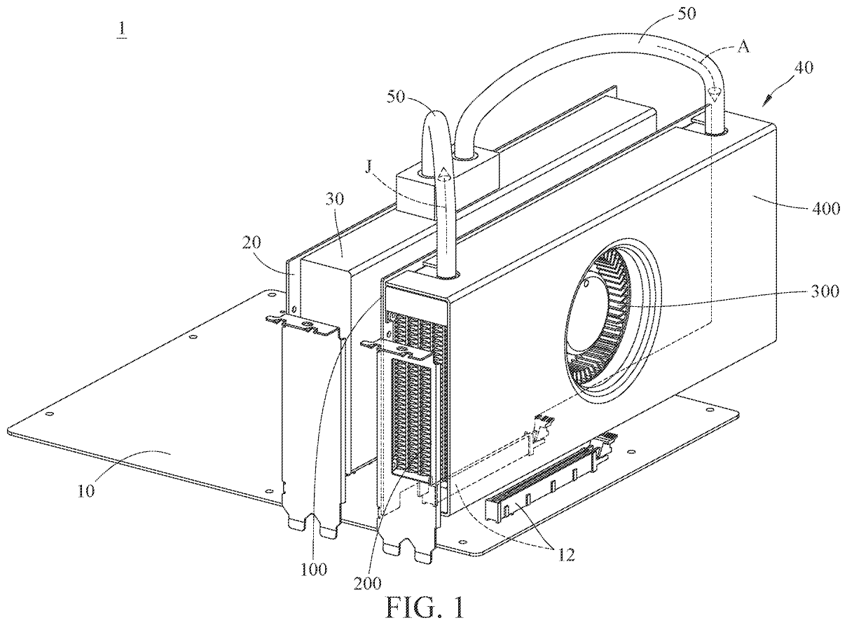

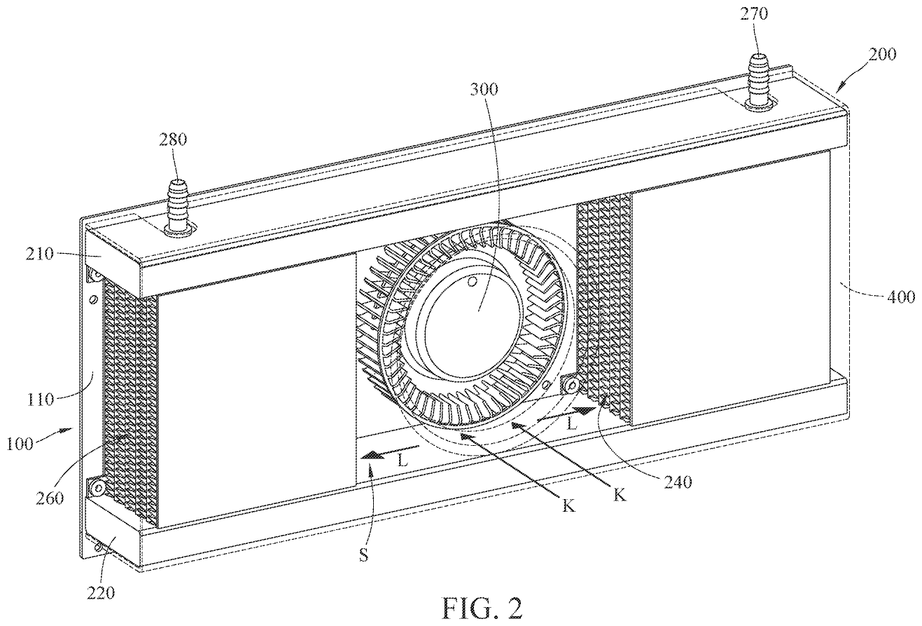

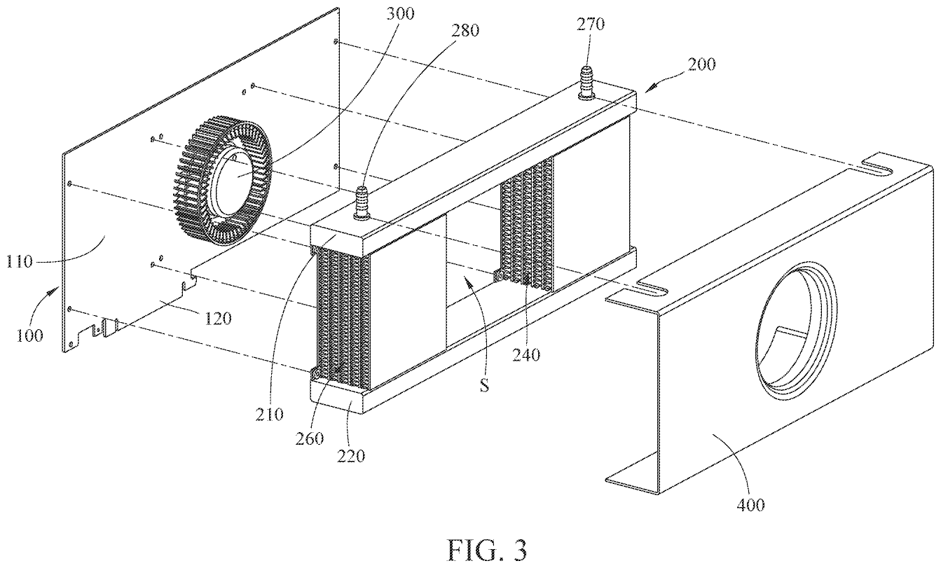

Please refer to FIG. 1 to FIG. 3, where FIG. 1 is a perspective view of an electronic assembly 1 in accordance with an embodiment of the disclosure, FIG. 2 is a perspective view of a water cooling assembly 40 of the electronic assembly 1 in FIG. 1, and FIG. 3 is an exploded view of the water cooling assembly 40 of the electronic assembly 1 in FIG. 1.

In this embodiment, the electronic assembly 1 is configured to be disposed in a server (not shown), and includes a circuit board 10, an interface card 20, a water cooling heatsink 30 and a water cooling assembly 40. The circuit board 10 has a plurality of electrical connectors 12. The plurality of electrical connectors 12 are, for example, interface card sockets. The interface card 20 is, for example, a display card, and is inserted into and electrically connected to one of the plurality of electrical connectors 12 of the circuit board 10. The water cooling heatsink 30 and the water cooling assembly 40 are configured to accommodate cooling liquid (not shown). The water cooling heatsink 30 is mounted on the interface card 20.

The water cooling assembly 40 includes a mounting plate 100, a water cooling radiator 200, an airflow generator 300 and a cover 400. The mounting plate 100 includes a mounting portion 110 and a plugging portion 120. The plugging portion 120 is connected to a side of the mounting portion 110. An appearance of the plugging portion 120 is, for example, the same as an appearance of a PCIe electrical connecting portion. The plugging portion 120 is be inserted into another of the plurality of electrical connectors 12 of the circuit board 10. The mounting plate 100 is, for example, a dummy interface card. That is, the mounting plate 100 is not a real interface card. Since the mounting plate 100 is not a real interface card, the mounting plate 100 does not include golden fingers configured to be electrically connected to one of the plurality of electrical connectors 12. Therefore, when the plugging portion 120 of the mounting plate 100 is inserted into one of the plurality of electrical connectors 12, the mounting plate 100 does not transmit signals.

In this embodiment, the advantage of the mounting plate 100 additionally provided in the water cooling assembly 40 and the water cooling radiator 200 fixed to the mounting plate 100 is that when the inner space of the server is almost fully occupied by electronic components, the mounting plate 100 can be inserted into one of the original electrical connectors 12 of the circuit board 10 to install the water cooling assembly 40. Accordingly, the distance between the water cooling assembly 40 and the interface card 20 can be shortened to save space via the small-sized mounting plate 100. In addition, the water cooling assembly 40 can be assembled via the mounting plate 100 inserted into one of the original electrical connectors 12 merely, without additionally installing a plurality of fastening components configured to fasten the water cooling assembly 40. Therefore, the inner space of the server can be saved while the convenience for installing the water cooling assembly 40 in the server can be improved.

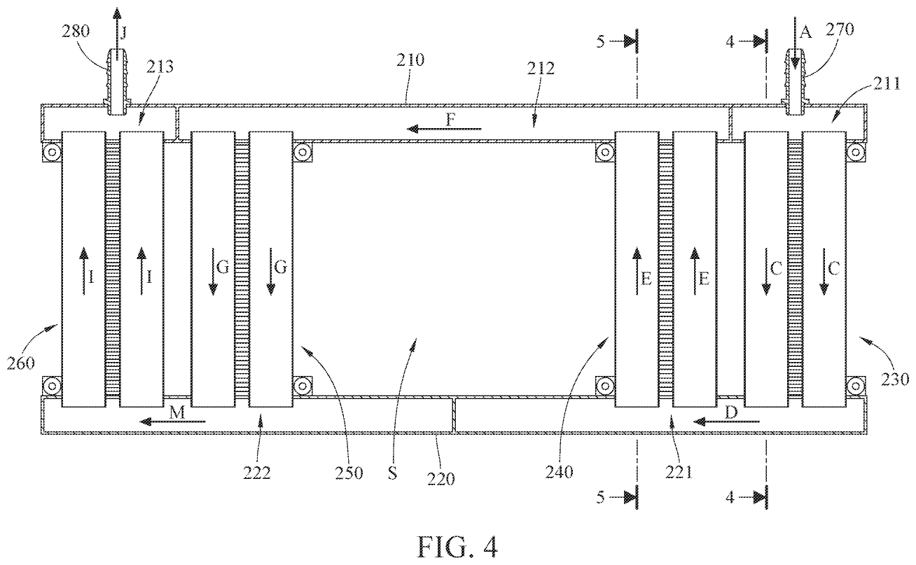

Please refer to FIG. 1 to FIG. 4, where FIG. 4 is a cross-sectional view of the water cooling assembly 40 of the electronic assembly 1 in FIG. 1. The water cooling radiator 200 is fastened to the mounting portion 110 of the mounting plate 100, and is in fluid communication with the water cooling heatsink 30 via two pipes 50. The water cooling radiator 200 includes a first water tank 210, a second water tank 220, a first heat dissipation channel structure 230, a second heat dissipation channel structure 240, a third heat dissipation channel structure 250, a fourth heat dissipation channel structure 260, a liquid inlet connector 270 and a liquid outlet connector 280. The first water tank 210 has a first chamber 211, a second chamber 212 and a third chamber 213, which are not in fluid communication with each other directly. The second water tank 220 has a fourth chamber 221 and a fifth chamber 222, which are not in fluid communication with each other directly. Two opposite ends of the first heat dissipation channel structure 230 are in fluid communication with the first chamber 211 of the first water tank 210 and the fourth chamber 221 of the second water tank 220, respectively. Two opposite ends of the second heat dissipation channel structure 240 are in fluid communication with the second chamber 212 of the first water tank 210 and the fourth chamber 221 of the second water tank 220, respectively. Two opposite ends of the third heat dissipation channel structure 250 are in fluid communication with the second chamber 212 of the first water tank 210 and the fifth chamber 222 of the second water tank 220, respectively. Two opposite ends of the fourth heat dissipation channel structure 260 are in fluid communication with the third chamber 213 of the first water tank 210 and the fifth chamber 222 of the second water tank 220, respectively. Since the chambers 211-213, 221, and 222 are in fluid communication with the heat dissipation channel structures 230-260, a length of a flow channel for the cooling liquid can be increased, thereby improving the heat dissipation capability.

The second heat dissipation channel structure 240 and the third heat dissipation channel structure 250 are spaced apart from each other so as to form an accommodation space S therebetween. The airflow generator 300 is, for example, a fan, and is located in the accommodation space S. The airflow generator 300 is configured to generate an airflow flowing through the first heat dissipation channel structure 230 to the fourth heat dissipation channel structure 260 of the water cooling radiator 200.

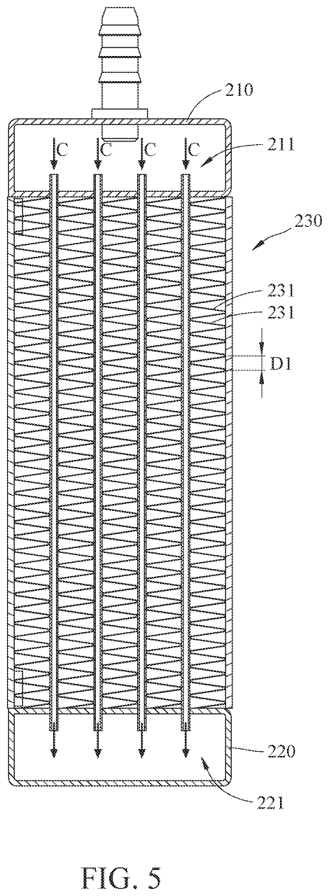

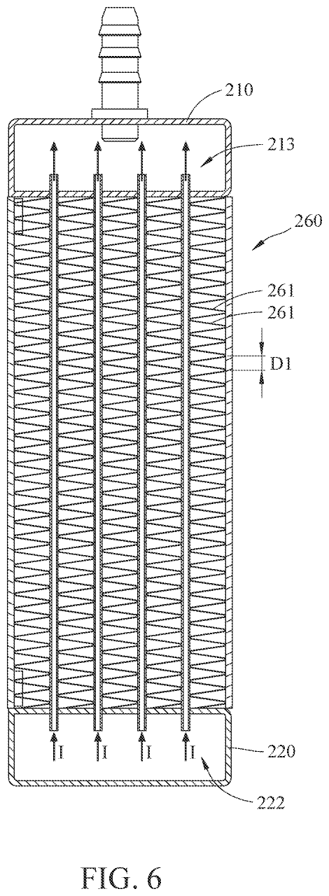

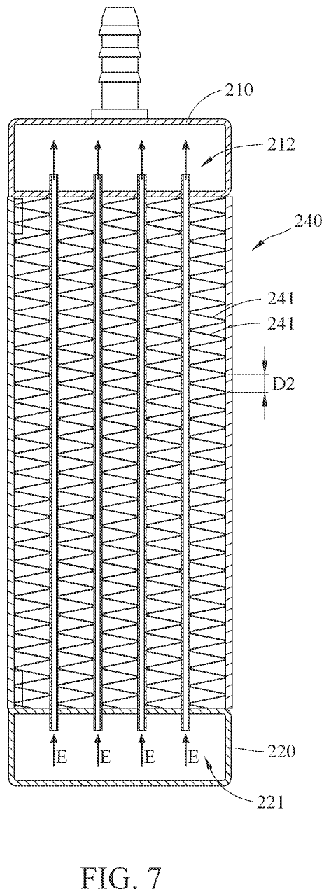

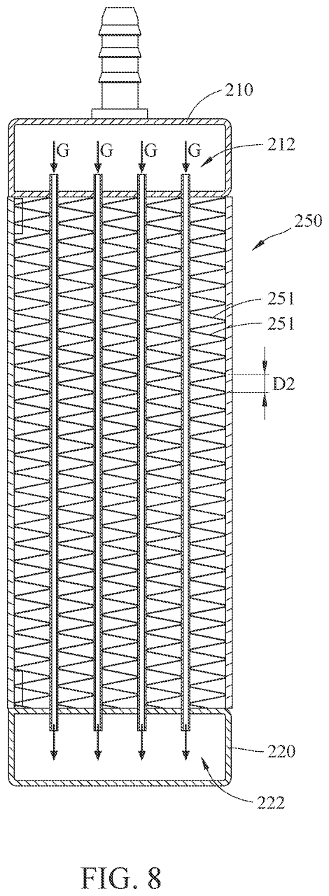

Please refer to FIG. 5 to FIG. 8, where FIG. 5 is a cross-sectional view of the first heat dissipation channel structure 230 of the electronic assembly 1 in FIG. 1, FIG. 6 is a cross-sectional view of the fourth heat dissipation channel structure 260 of the electronic assembly 1 in FIG. 1, FIG. 7 is a cross-sectional view of the second heat dissipation channel structure 240 of the electronic assembly 1 in FIG. 1, and FIG. 8 is a cross-sectional view of the third heat dissipation channel structure 250 of the electronic assembly 1 in FIG. 1.

The first heat dissipation channel structure 230 has a plurality of heat dissipation structures 231. The second heat dissipation channel structure 240 has a plurality of heat dissipation structures 241. The third heat dissipation channel structure 250 has a plurality of heat dissipation structures 251. The fourth heat dissipation channel structure 260 has a plurality of heat dissipation structures 261. The airflow generated by the airflow generator 300 flows through the plurality of heat dissipation structures 231, 241, 251, and 261 to cool the cooling liquid. A distance D1 between each two adjacent heat dissipation structures 231 of the first heat dissipation channel structure 230 and a distance D1 between each two adjacent heat dissipation structures 261 of the fourth heat dissipation channel structure 260 are smaller than a distance D2 between each two adjacent heat dissipation structures 241 of the second heat dissipation channel structure 240 and a distance D2 between each two adjacent heat dissipation structures 251 of the third heat dissipation channel structure 250. For example, the distance D1 is 2.6 millimeters, and two distance D2 is 3.2 millimeters, respectively. Accordingly, the wind resistance generated when the airflow flows can be effectively reduced so as to improve the efficiency of the heat dissipation.

Please refer to FIG. 1 to FIG. 4 again. The liquid inlet connector 270 and the liquid outlet connector 280 are mounted on the first water tank 210, and are in fluid communication with the first chamber 211 and the third chamber 213, respectively. The cover 400 is mounted on the mounting plate 100, and the cover 400 and the mounting plate 100 surround the water cooling radiator 200.

As shown in FIG. 2, in this embodiment, the cooling liquid located in the water cooling heatsink 30 flows from the liquid inlet connector 270 into the first chamber 211 along a direction A after the cooling liquid absorbs the heat generated by the interface card 20. Then, the cooling liquid flows from the first chamber 211 into the fourth chamber 221 along a direction C via the first heat dissipation channel structure 230. Then, the cooling liquid flows in the fourth chamber 221 along a direction D, and then flows from the fourth chamber 221 into the second chamber 212 along a direction E via the second heat dissipation channel structure 240. Then, the cooling liquid flows in the second chamber 212 along a direction F, and then flows from the second chamber 212 into the fifth chamber 222 along a direction G via the third heat dissipation channel structure 250. Then, the cooling liquid flows in the fifth chamber 222 along a direction H, and then flows from the fifth chamber 222 into the third chamber 213 along a direction I via the fourth heat dissipation channel structure 260. Finally, the cooling liquid flows from the liquid outlet connector 280 out of the third chamber 213 along a direction J, and flows back to the water cooling heatsink 30.

As shown in FIG. 2, the airflow generated by the airflow generator 300 flows towards the water cooling radiator 200 along a direction K, and flows through the plurality of heat dissipation structures 231, 241, 251, and 261 of the first heat dissipation channel structure 230 to the fourth heat dissipation channel structure 260 along a direction L, respectively. Accordingly, when the cooling liquid absorbing the heat generated by the interface card 20 flows in the heat dissipation channel structures 230-260, the airflow generated by the airflow generator 300 can cool the cooling liquid via flowing through the plurality of heat dissipation structures 231, 241, 251, and 261. Therefore, the cooling liquid can cool the interface card 20 circularly.

According to the water cooling assembly and the electronic assembly as described in the above embodiments, since the mounting plate fastening the water cooling radiator is additionally provided in the water cooling assembly, when the inner space of the server is almost fully occupied by electronic components, the mounting plate can be inserted into one of the original electrical connectors of the circuit board to install the water cooling assembly. Accordingly, the distance between the water cooling assembly and the interface card can be shortened to save space via the small-sized mounting plate. In addition, the water cooling assembly can be assembled via the mounting plate inserted into one of the original electrical connectors merely, without additionally installing a plurality of fastening components configured to fasten the water cooling assembly. Therefore, the inner space of the server can be saved while the convenience for installing the water cooling assembly in the server can be improved.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A water cooling assembly, configured to be mounted at an electrical connector of a circuit board, the water cooling assembly comprising:
a mounting plate, comprising a mounting portion and a plugging portion, wherein the plugging portion is connected to a side of the mounting portion, and the plugging portion is configured to be inserted into the electrical connector of the circuit board; and
a water cooling radiator, fastened to the mounting portion of the mounting plate.

2. The water cooling assembly according to claim 1, wherein the mounting plate is a dummy interface card.

3. The water cooling assembly according to claim 1, wherein an appearance of the plugging portion is the same as an appearance of a PCIe electrical connecting portion.

4. The water cooling assembly according to claim 1, wherein the water cooling radiator comprises a first water tank, a second tank, a first heat dissipation channel structure, a second heat dissipation channel structure, a third heat dissipation channel structure and a fourth heat dissipation channel structure, the first water tank has a first chamber, a second chamber and a third chamber which are not in fluid communication with each other directly, the second water tank has a fourth chamber and a fifth chamber which are not in fluid communication with each other directly, two opposite ends of the first heat dissipation channel structure are in fluid communication with the first chamber of the first water tank and the fourth chamber of the second water tank, respectively, two opposite ends of the second heat dissipation channel structure are in fluid communication with the second chamber of the first water tank and the fourth chamber of the second water tank, respectively, two opposite ends of the third heat dissipation channel structure are in fluid communication with the second chamber of the first water tank and the fifth chamber of the second water tank, respectively, and two opposite ends of the fourth heat dissipation channel structure are in fluid communication with the third chamber of the first water tank and the fifth chamber of the second water tank, respectively.

5. The water cooling assembly according to claim 4, wherein each of the first heat dissipation channel structure to the fourth heat dissipation channel structure has a plurality of heat dissipation structures.

6. The water cooling assembly according to claim 5, wherein a distance between each two of the plurality of heat dissipation structures that are adjacent to each other of the first heat dissipation channel structure and the fourth heat dissipation channel structure is smaller than a distance between each two of the plurality of heat dissipation structures that are adjacent to each other of the second heat dissipation channel structure and the third heat dissipation channel structure.

7. The water cooling assembly according to claim 6, wherein the distance between each two of the plurality of heat dissipation structures that are adjacent to each other of the first heat dissipation channel structure and the fourth heat dissipation channel structure is 2.6 millimeters, and the distance between each two of the plurality of heat dissipation structures that are adjacent to each other of the second heat dissipation channel structure and the third heat dissipation channel structure is 3.2 millimeters.

8. The water cooling assembly according to claim 4, wherein the second heat dissipation channel structure and the third heat dissipation channel structure are spaced apart from each other so as to form an accommodation space therebetween.

9. The water cooling assembly according to claim 8, further comprising an airflow generator, wherein the airflow generator is located in the accommodation space, and the airflow generator is configured to generate an airflow flowing through the first heat dissipation channel structure to the fourth heat dissipation channel structure of the water cooling radiator.

10. The water cooling assembly according to claim 4, wherein the water cooling radiator further comprises a liquid inlet connector and a liquid outlet connector, the liquid inlet connector and the liquid outlet connector are mounted on the first water tank, and the liquid inlet connector and the liquid outlet connector are in fluid communication with the first chamber and the third chamber, respectively.

11. The water cooling assembly according to claim 4, further comprising a cover, wherein the cover is mounted on the mounting plate, and the cover and the mounting plate surround the water cooling radiator.

12. An electronic assembly, comprising:
a circuit board, having a plurality of electrical connectors;
an interface card, inserted into and electrically connected to one of the plurality of electrical connectors of the circuit board;
a water cooling heatsink, mounted on the interface card; and
a water cooling assembly, comprising:
a mounting plate, comprising a mounting portion and a plugging portion, wherein the plugging portion is connected to a side of the mounting portion, and the plugging portion is be inserted into another of the plurality of electrical connectors of the circuit board; and
a water cooling radiator, fastened to the mounting portion of the mounting plate and being in fluid communication with the water cooling heatsink via pipes.
